(19) United States
(12) Patent Application Publication
(10) Pub. No.: US 2023/0324130 A1
(43) Pub. Date: Oct. 12, 2023

(54) HEAT DISSIPATION MODULE AND MANUFACTURING METHOD THEREOF

(71) Applicant: TAIWAN MICROLOOPS CORP., New Taipei City (TW)

(72) Inventor: Chun-Hung LIN, New Taipei City (TW)

(21) Appl. No.: 17/744,402

(22) Filed: May 13, 2022

(30) Foreign Application Priority Data
Apr. 12, 2022 (TW) 111113859

(51) Int. Cl. F28D 15/02; F28D 15/04; H05K 7/20

(52) U.S. Cl. CPC F28D 15/0275; F28D 15/046; F28D 15/0233; H05K 7/20336

(57) ABSTRACT

A heat dissipation module includes a housing, a first capillary structure, and at least two heat pipe assemblies. The outer periphery of the housing has multiple sidewalls. At least two sidewalls have an opening and an inner rim formed inside the opening. The first capillary structure covers the interior of the housing and is disposed along each inner rim. Each heat pipe assembly includes a cover plate, multiple heat pipes and a second capillary structure. Each cover plate has multiple through holes and an inner sidewall. Each heat pipe has an open end connected and sealed with each corresponding through hole. Each second capillary structure covers each inner sidewall and the interior of the heat pipes. Each cover plate covers each corresponding opening, such that each second capillary structure is attached closely to the first capillary structure.

### BACKGROUND OF THE DISCLOSURE

### Technical Field

The technical field relates to a heat dissipation structure integrated with a vapor chamber and a heat pipe, and more particularly relates to a heat dissipation module and a manufacturing method thereof.

### Description of Related Art

Heat pipes and vapor chambers featuring good thermal conductivity are widely used for heat dissipation. Although the heat pipes can maintain a consistent flow direction of the gaseous working fluid inside the heat pipes, the amount of heat conducted by the heat pipes is limited due to the limitation of volume. Although the vapor chambers have spacious heating areas that provide direct attachment and conduction to the heat source, the flow direction of the gaseous working fluid is quite turbulent, which may limit the heat conduction and dissipation performance.

In order to solve the aforementioned problems, related-art manufacturers have combined the heat pipe with the vapor chamber to form a thermally conductive structure, so that the heat pipe is connected to a side of the vapor chamber, and the inner space of the heat pipe and the inner space of the vapor chamber communicate to each other.

However, the related-art combined structure of the vapor chamber and the heat pipe has the following problems: the capillary tissue inside the heat pipe cannot be attached to the capillary tissue inside the vapor chamber, thereby leading to the interruption or discontinuity of the flow of the liquid-state working fluid, which greatly reduces the heat conduction and dissipation efficiency.

In view of the aforementioned problems, the discloser proposed this disclosure based on his expert knowledge and elaborated researches to overcome the problems of the related art.

### SUMMARY OF THE DISCLOSURE

This disclosure is directed to a heat dissipation module and a manufacturing method thereof, which use a cover plate for covering a corresponding opening and driving a second capillary structure to be closely attached with a first capillary structure to achieve the advantages of a smooth reflow of the working fluid and a stable heat dissipation efficiency of the heat dissipation module.

In an embodiment of this disclosure, this disclosure provides a heat dissipation module, including: a housing, having a plurality of sidewalls on the outer periphery thereof, and at least two of the sidewalls having an opening and an inner rim formed inside the opening; a first capillary structure, covering the housing the interior of the housing and disposed along each inner rim; and at least two heat pipe assemblies, each including a cover plate, a plurality of heat pipes and a second capillary structure, and each of the cover plates having a plurality of through holes and an inner sidewall, and each of the heat pipes having an open end, and the open end of each heat pipe coupled and sealed with each corresponding through hole, and each second capillary structure covering each inner sidewall and the interior of the plurality of heat pipes; wherein each cover plate covers each corresponding opening, and each second capillary structure and the first capillary structure are attached to each other closely

In an embodiment of this disclosure, this disclosure provides a manufacturing method of the heat dissipation module, and the method includes the steps of: (a) providing a housing, which has a plurality of sidewalls disposed on the outer periphery of the housing, and at least two of the sidewalls having an opening and an inner rim formed at the interior of the opening; (b) providing a first capillary structure, which covers the interior of the housing and is disposed along each inner rim; (c) providing at least two cover plates, each having a plurality of through holes and an inner sidewall; (d) providing a plurality of heat pipes, each having an open end, and each heat pipe coupled and sealed with each corresponding through hole by the open end; (e) providing at least two second capillary structure, each covering each inner sidewall and the interior of the plurality of heat pipes; and (f) covering each opening by each cover plate to make each second capillary structure and the first capillary structure be attached closely with each other.

Based on the above, the outer periphery of each second capillary structure and the outer periphery of the first capillary structure are attached closely with each other to ensure that the first capillary structure keeps connecting with each second capillary structure, such that the liquid-state working fluid in the heat dissipation module may reflow smoothly from the heat pipe to the first capillary structure of the housing through the second capillary structure to achieve the advantages of a smooth reflow of working fluid and a stable heat dissipation efficiency of the heat dissipation module.

Based on the above, at least two of the sidewalls of the housing have an opening, and each heat pipe assembly is installed corresponding to the opening, such that the heat dissipation module is a structure having heat pipes passing out from two sides or a multiple of sides to let the heat dissipation module have bidirectional or multidirectional heat-exchange airflow, so as to improve the heat dissipation efficiency of the heat dissipation module.

### BRIEF DESCRIPTION OF THE DRAWINGS

FIG. 1 is a flow chart of a manufacturing method of a heat dissipation module in accordance with this disclosure;

FIG. 2 is a schematic view of a first capillary structure covering the interior of a housing and set along each inner rim in accordance with this disclosure;

FIG. 3 is a schematic view of each second capillary structure covering each inner sidewall and the interior of a plurality of heat pipes in accordance with this disclosure;

FIG. 4 is a schematic view of each cover plate covering each corresponding opening in accordance with this disclosure;

FIG. 5 is a perspective view of a heat dissipation module of this disclosure;

FIG. 6 is a cross-sectional view of a heat dissipation module of this disclosure;

FIG. 7 is another cross-sectional view of a heat dissipation module of this disclosure;

FIG. 8 is another perspective view of a heat dissipation module of this disclosure;

FIG. 9 is a further perspective view of a heat dissipation module of this disclosure;

FIG. 10 is a cross-sectional view of a heat dissipation module in accordance with another embodiment of this disclosure; and

FIG. 11 is a top view of a heat dissipation module in accordance with a further embodiment of this disclosure.

### DETAILED DESCRIPTION

The technical contents of this disclosure will become apparent with the detailed description of embodiments accompanied with the illustration of related drawings as follows. It is intended that the embodiments and drawings disclosed herein are to be considered illustrative rather than restrictive.

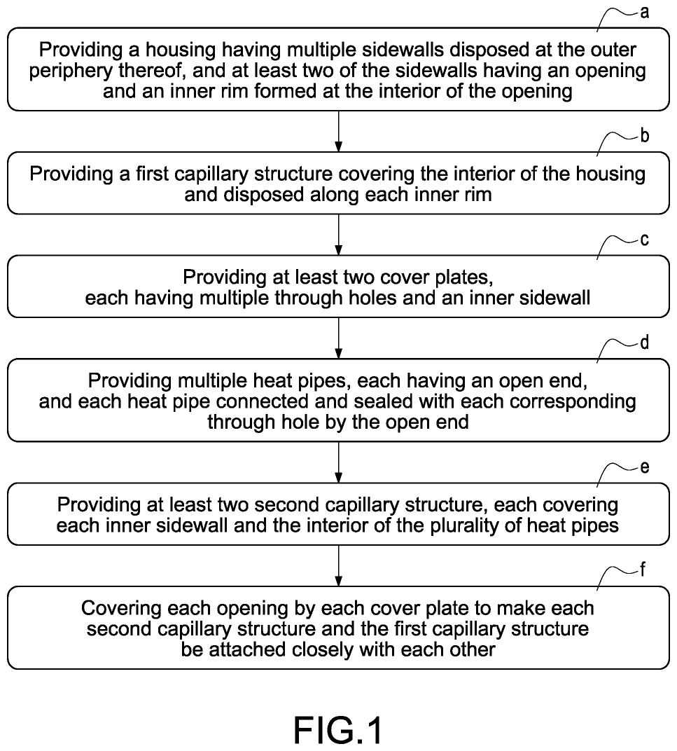

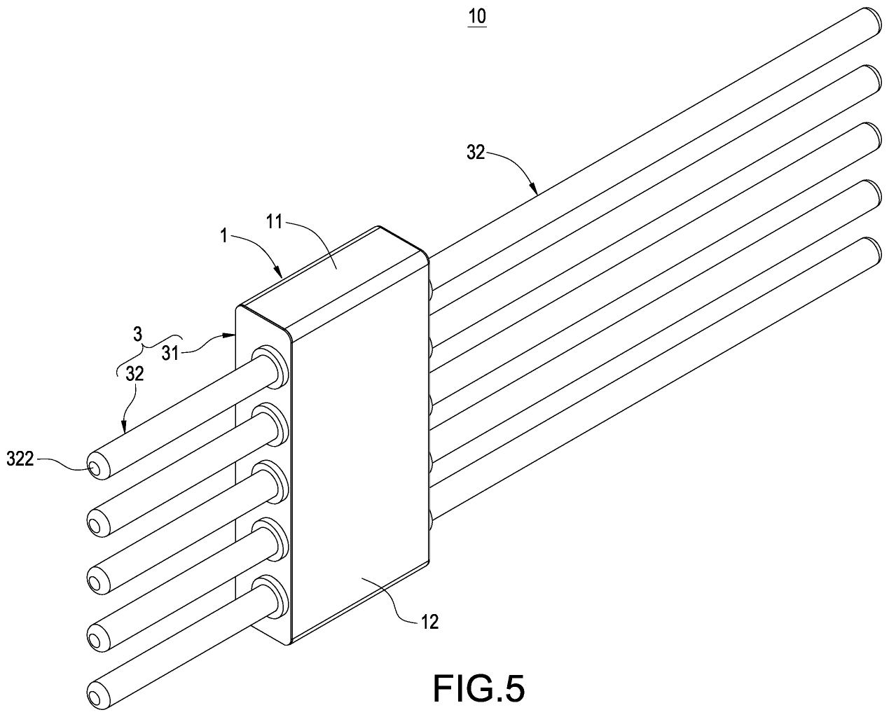

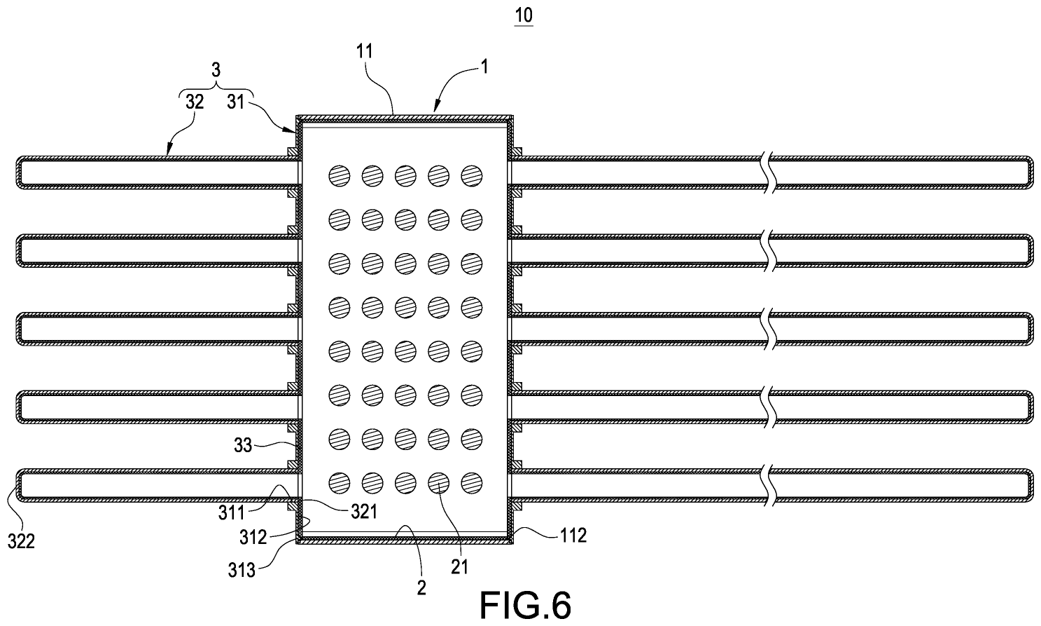

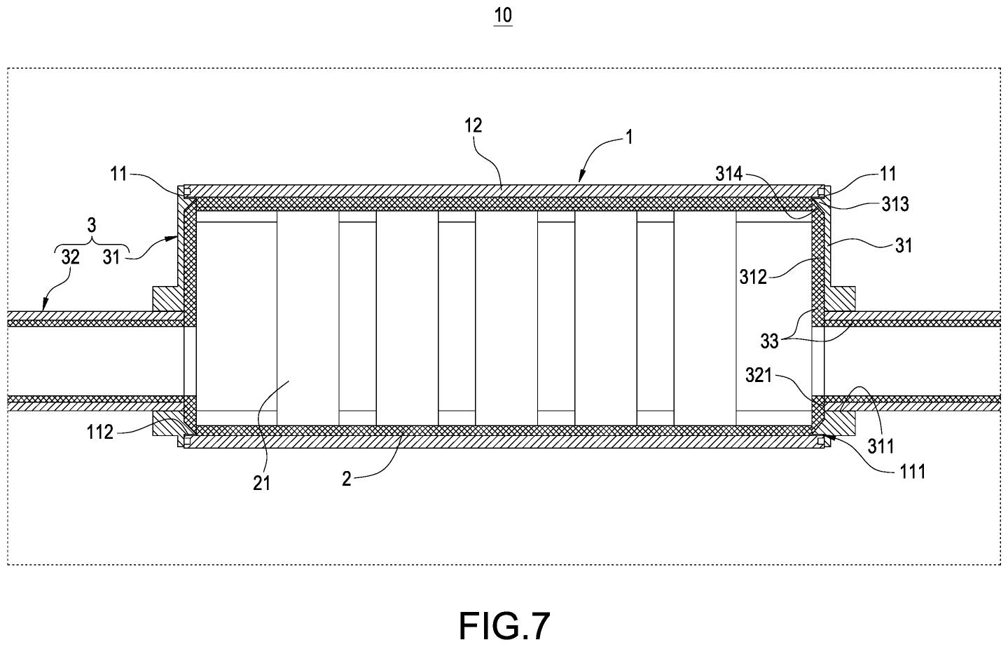

With reference to FIGS. 1 to 9 for a heat dissipation module and a manufacturing method of the heat dissipation module in accordance with this disclosure, the heat dissipation module 10 includes a housing 1, a first capillary structure 2 and at least two heat pipe assemblies 3.

With reference to FIG. 1 for the flow chart of a manufacturing method of the heat dissipation module 10 of this disclosure, the method includes the following steps.

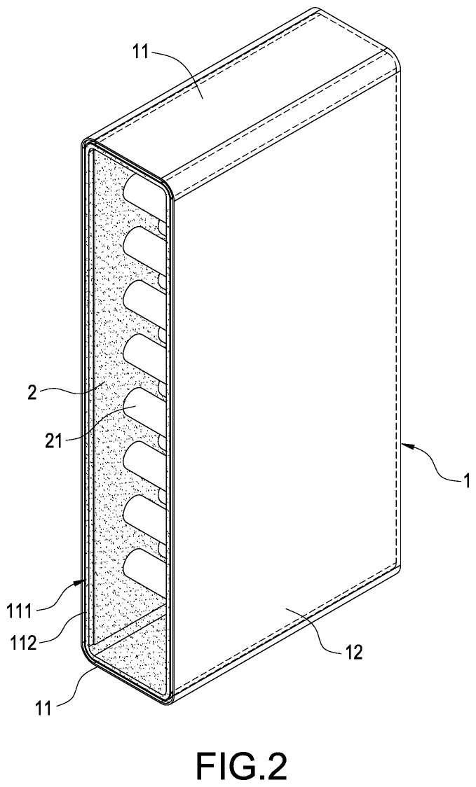

First, in the step (a) as shown in FIGS. 1 and 2, a housing 1 is provided, and the outer periphery of the housing 1 has a plurality of sidewalls 11, and at least two of the sidewalls 11 have an opening 111 and an inner rim 112 formed inside the opening 111.

In FIGS. 2, and 4 to 9, the housing 1 has a top wall 12 and a bottom wall 13, and the top wall 12 or the bottom wall 13 is thermally attached to a heat generating element 100, and the plurality of sidewalls 11 is disposed between the top wall 12 and the bottom wall 13, and connected with the outer periphery of the top wall 12 and the bottom wall 13.

The housing 1 of this embodiment is in a rectangular shape. This disclosure is not limited to such shape only, and the housing 1 may also be in a triangular shape, a pentagonal shape, or any other geometric shape. In this embodiment, there are two sidewalls 11 having the openings 111 and the two sidewalls are facing each other. This disclosure is not limited to such arrangement only, the quantity and position of the sidewalls 111 having the openings 111 may be adjusted according to the actual installation environment.

Second, in the step (b) as shown in FIG. 1 and FIG. 2, a first capillary structure 2 covers the interior of the housing 1 and set along each inner rim 112.

In FIGS. 2, 4, 6 and 7, the interior of the housing 1 has a plurality of support columns 21. Two ends of each support column 21 abut against the top wall 12 and the bottom wall 13 respectively to enhance the structural strength of the housing 1 and prevent the housing 1 from being deformed easily.

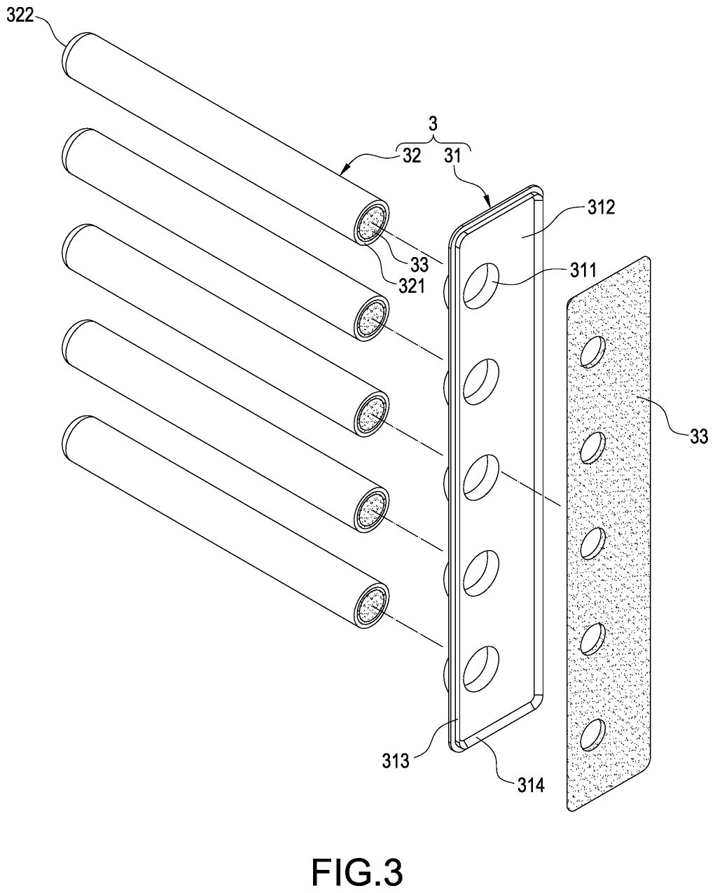

Third, in the step (c) as shown in FIG. 1 and FIG. 3, at least two cover plates 31 are provided, and each cover plate 31 has a plurality of through holes 311, and each cover plate 31 has an inner sidewall 312.

Specifically, in FIGS. 3 to 9, each inner sidewall 312 has a positioning ring 313 extended around the outer periphery of the plurality of through holes 311, and the inner circumference of each positioning ring 313 has an inclined ring surface 314 with a diameter tapered in a direction away from the inner sidewall 312, and the size of the outer periphery of each inclined ring surface 314 is greater than the size of the inner circumference of the first capillary structure 2 disposed along each inner rim 112.

Fourth, in the step (d) as shown in FIG. 1 and FIG. 3, a plurality of heat pipes 32 is provided, and an end of each heat pipe 32 has an open end 321 and another end has a closed end 322, and each heat pipe 32 passes and seals each corresponding through hole 311 by the open end 321. In other words, each heat pipe 32 passes each corresponding through hole 311 by the open end 321 and is soldered to the cover plate 31 along the through hole 311.

Fifth, in the step (e) as shown in FIG. 1 and FIG. 3, at least two second capillary structure 33 are provided, and each second capillary structure 33 covers each inner sidewall 312 and the interior of the plurality of heat pipes 32.

Further, in FIGS. 3 to 4 and 6 to 7, each second capillary structure 33 is filled into the interior of each positioning ring 313 and covers each inclined ring surface 314 to make each second capillary structure 33 stably cover each inner sidewall 312.

In addition, each heat pipe assembly 3 includes a cover plate 31, a plurality of heat pipes 32 and a second capillary structure 33, and each second capillary structure 33 of this embodiment covers the whole interior of the plurality of heat pipes 32. This disclosure is not limited to such arrangement only. The first capillary structure 2 and the second capillary structure 33 are a powder sintered body respectively.

Sixth, in the step (f) as shown in FIG. 1 and FIGS. 4 to 7, each cover plate 31 covers each corresponding opening 111. In other words, each cover plate 31 is soldered to the housing 1 along the opening 111 to make each second capillary structure 33 and the first capillary structure 2 be attached closely with each other.

Finally, this disclosure further provides a working fluid (not shown in the figures), and the working fluid is filled into the housing 1 and the plurality of heat pipes 32, and the housing 1 and the plurality of heat pipes 32 are vacuumed and sealed, so as to complete the assembly of the heat dissipation module 10. The housing 1, the cover plate 31 and the first capillary structure 2 jointly constitute a vapor chamber.

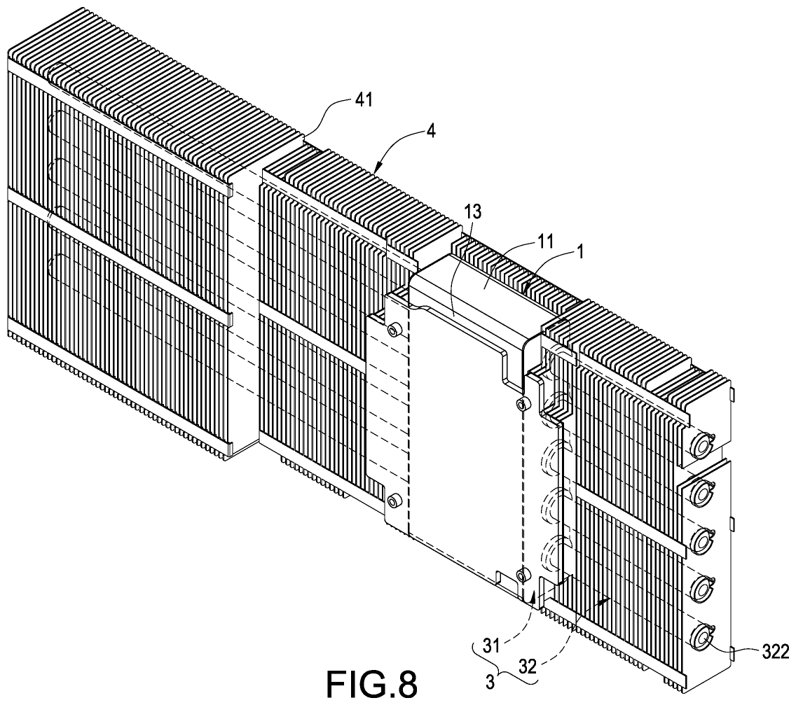

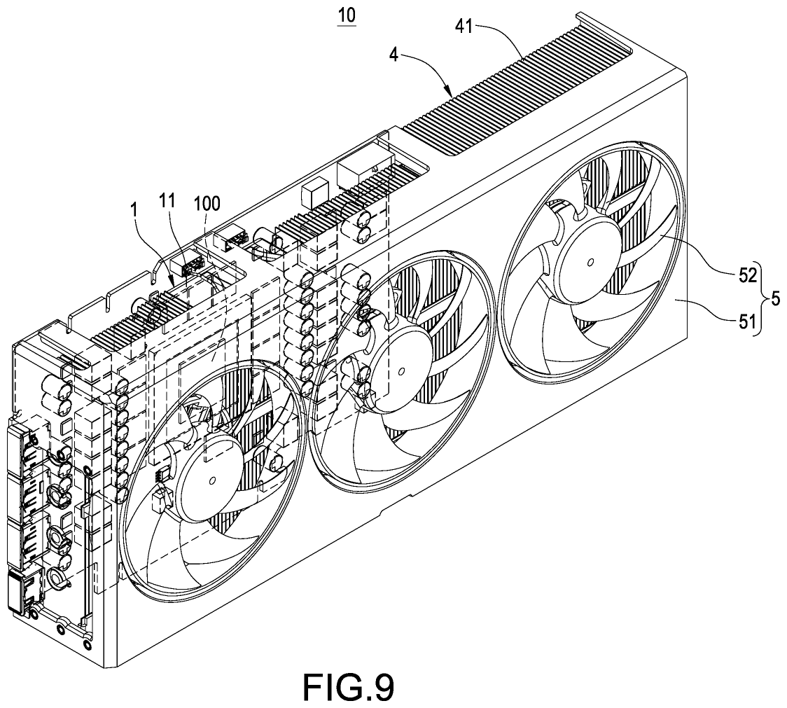

In FIGS. 8 to 9, the heat dissipation module 10 of this disclosure further includes a fin assembly 4 and a fan assembly 5, and the fin assembly 4 includes a plurality of fins 41 adapted to sheathe the plurality of heat pipes 32, and the fan assembly 5 includes a fixed mount 51 stacked with the fin assembly 4 and a plurality of fans 52 installed to the fixed mount 51 and arranged corresponding to the housing 1 and the plurality of heat pipes 32. The fin assembly 4 and the fan assembly 5 are provided for improving the heat dissipation efficiency of the heat dissipation module 10.

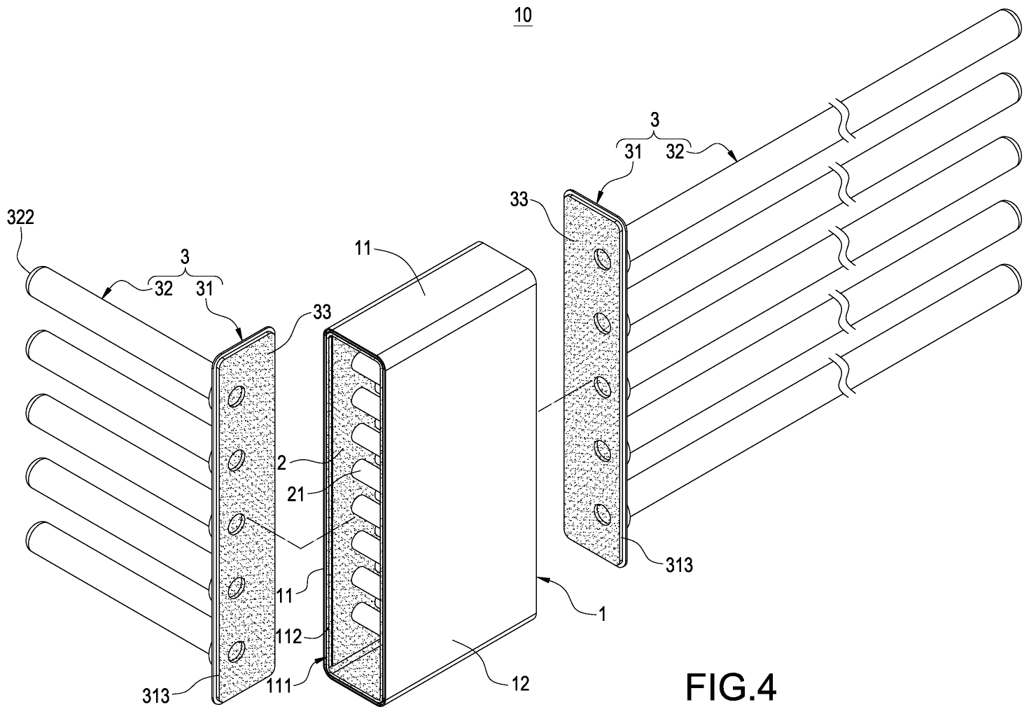

With reference to FIGS. 4 to 7 for the status of use of the heat dissipation module 10 of this disclosure, the first capillary structure 2 covers the interior of the housing 1 and set along each inner rim 112, and each second capillary structure 33 covers each inner sidewall 312 and the interior of the plurality of heat pipes 32. When each cover plate 31 covers each corresponding opening 111, the position of each second capillary structure 33 and the position of the outer periphery of the first capillary structure 2 are overlapped with each other, so that each cover plate 31 drives each second capillary structure 33 to squeeze the first capillary structure 2. As a result, the outer periphery of each second capillary structure 33 and the outer periphery of the first capillary structure 2 are attached closely with each other to ensure that the first capillary structure 2 keeps connecting each second capillary structure 33 and the liquid-state working fluid may smoothly reflow from the heat pipe 32 to the first capillary structure 2 of the housing 1 through the second capillary structure 33, so as to achieve the advantages of a smooth reflow of the working fluid and a stable heat dissipation efficiency of the heat dissipation module 10.

In FIGS. 8 to 9, the top wall 12 or the bottom wall 13 of the housing 1 is thermally attached to a heat generating element 100, and at least two of the sidewalls 11 have an opening 111, and each heat pipe assembly 3 is installed corresponding to the opening 111, such that the heat dissipation module 10 is a structure having the heat pipes 32 on two sides or multiple sides to let the heat dissipation module 10 have a bidirectional or multidirectional heat-exchange airflow, so as to improve the heat dissipation efficiency of the heat dissipation module 10.

In addition, each second capillary structure 33 is filled into the interior of each positioning ring 313 and covers each inclined ring surface 314, and the positioning ring 313 may enhance the structural strength of the second capillary structure 33, so that the second capillary structure 33 may not be deformed easily and has sufficient strength to squeeze the first capillary structure 2, and the inclined ring surface 314 may expand the contact surface of the second capillary structure 33.

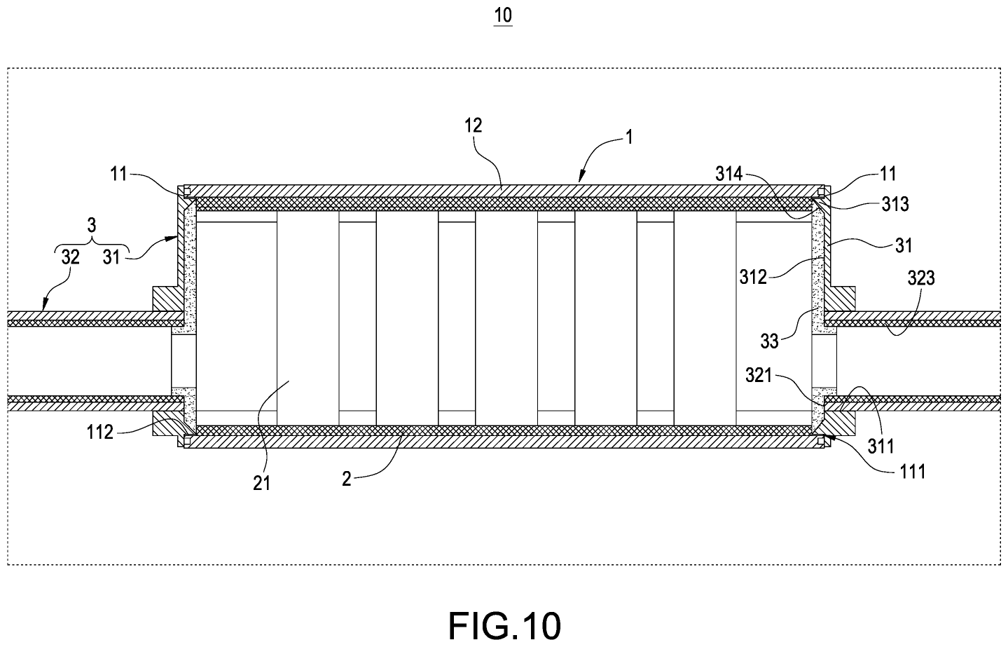

With reference to FIG. 10 for a heat dissipation module 10 in accordance with another embodiment of this disclosure, the embodiment as shown in FIG. 10 is substantially the same as the embodiments as shown in FIGS. 1 to 9, except that each heat pipe 32 of this embodiment has a third capillary structure 323 installed in the heat pipe 32.

Specifically, each heat pipe 32 of this embodiment has a third capillary structure 323 disposed therein, and each second capillary structure 33 covers the interior of each open end 321 and is stacked on each third capillary structure 323. This disclosure is not limited to such arrangement only. The first capillary structure 2 and the second capillary structure 33 are powder sintered bodies respectively, and the third capillary structure 323 is a powder sintered body, a mesh body, a fiber body, a groove, or any combination of the above. In this way, the same functions and effects of the embodiments as shown in FIGS. 1 to 9 may be achieved.

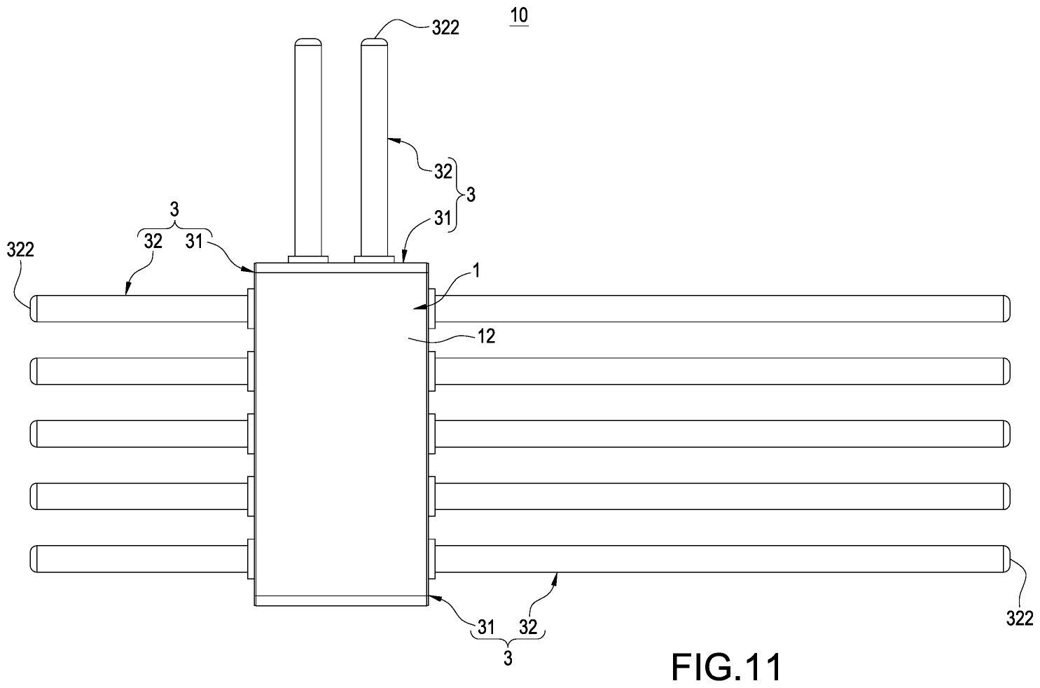

With reference to FIG. 11 for a heat dissipation module 10 in accordance with another embodiment of this disclosure, the embodiment as shown in FIG. 11 is substantially the same as the embodiments as shown in FIGS. 1 to 9, except that there are three sidewalls 11 having the openings 111 and there are three heat pipe assemblies 3 in this embodiment This disclosure is not limited to such arrangement only, and the quantity and position of sidewalls 11 having the openings 111 may be adjusted according to the actual accommodation space of the heat dissipation module 10, and each heat pipe assembly 3 is installed corresponding to each opening 111.

In summation of the description above, the heat dissipation module of this disclosure and its manufacturing method can surely achieve the expected objectives and overcome the drawbacks of the related art. While this disclosure has been described by means of specific embodiments, numerous modifications and variations could be made thereto by those skilled in the art without departing from the scope and spirit of this disclosure set forth in the claims.

What is claimed is:

1. A heat dissipation module, comprising:
a housing, comprising a plurality of sidewalls on an outer periphery thereof, and at least two of the sidewalls respectively comprising an opening and an inner rim disposed inside the opening;
a first capillary structure, covering interior of the housing and disposed along the inner rim; and
at least two heat pipe assemblies, each heat pipe assembly comprising a cover plate, a plurality of heat pipes and a second capillary structure, and the cover plate comprising a plurality of through holes and an inner sidewall, and each of the heat pipes comprising an open end, and each heat pipe coupled and sealed with each through hole correspondingly by the open end, and each second capillary structure covering each inner sidewall and interior of the heat pipes;
wherein the cover plate covers the opening correspondingly, and the second capillary structure and the first capillary structure are attached to each other.

2. The heat dissipation module according to claim 1, wherein the inner sidewall comprises a positioning ring extended around an outer periphery of the through holes, and the second capillary structure is filled in interior of the positioning ring.

3. The heat dissipation module according to claim 2, wherein the positioning ring comprises an inclined ring surface disposed at an inner circumference thereof with a diameter tapered in a direction away from the inner sidewall, and a size of an outer periphery of the inclined ring surface is greater than a size of an inner circumference of the first capillary structure disposed along the inner rim, and the second capillary structure covers the inclined ring surface.

4. The heat dissipation module according to claim 1, wherein the housing further comprises a top wall and a bottom wall, and the housing further comprises a plurality of support columns disposed inside, and each support column comprising two ends abutting against the top wall and the bottom wall.

5. The heat dissipation module according to claim 1, wherein the second capillary structure covers whole interior of the heat pipes.

6. The heat dissipation module according to claim 1, wherein each of the heat pipes comprises a third capillary structure disposed inside, and the second capillary structure covers interior of the open end and is stacked on the third capillary structure.

7. The heat dissipation module according to claim 1, further comprising a fin assembly and a fan assembly, and the fin assembly comprising a plurality of fins adapted to sheathe the heat pipes, and the fan assembly comprising a fixed mount stacked with the fin assembly and a plurality of fans installed to the fixed mount and arranged corresponding to the housing and the heat pipes.

8. A manufacturing method of a heat dissipation module, the method comprising the steps of:
(a) providing a housing, which comprises a plurality of sidewalls disposed on outer periphery of the housing, and at least two of the sidewalls respectively comprising an opening and an inner rim disposed inside the opening;
(b) providing a first capillary structure, which covers interior of the housing and is disposed along the inner rim;
(c) providing at least two cover plates, wherein each cover plate comprises a plurality of through holes and an inner sidewall;
(d) providing a plurality of heat pipes, wherein each heat pipe comprises an open end, and each heat pipe is coupled and sealed each through hole by the open end;
(e) providing at least two second capillary structures, each second capillary structure covers the inner sidewall and interior of the heat pipes; and
(f) covering the opening by each cover plate to make each second capillary structure and the first capillary structure be attached with each other.

9. The manufacturing method according to claim 8, wherein in the step (e), each second capillary structure covers whole interior of the heat pipes.

10. The manufacturing method according to claim 8, wherein in the step (e), each of the heat pipes comprises a third capillary structure disposed therein, and each second capillary structure covers interior of the open end and is stacked on the third capillary structure.

11. The manufacturing method according to claim 8, wherein in the step (c), the inner sidewall comprises a positioning ring extended around an outer periphery of the through holes, and an inner circumference of the positioning ring comprises an inclined ring surfaces with a diameter tapered in a direction away from the inner sidewall, and a size of an outer periphery of the inclined ring surface is greater than a size of an inner circumference of the first capillary structure disposed along the inner rim, and in the step (e), each second capillary structure is filled into interior of the positioning ring and covers the inclined ring surface.
